(19) United States
(12) Patent Application Publication
(10) Pub. No.: US 2025/0022522 A1
(43) Pub. Date: Jan. 16, 2025

(54) ELECTROCHEMICAL CHARGE STORAGE DEVICE

(71) Applicant: COMMISSARIAT À L’ENERGIE ATOMIQUE ET AUX ENERGIES ALTERNATIVES, PARIS (FR)

(72) Inventors: Sami OUKASSI, GRENOBLE CEDEX 9 (FR); Tifenn HIRTZLIN, GRENOBLE CEDEX 9 (FR); Massimiliano MELFI, GRENOBLE CEDEX 9 (FR); Ngoc-Anh NGUYEN, GRENOBLE CEDEX 9 (FR); Elisa VIANELLO, GRENOBLE CEDEX 9 (FR)

(21) Appl. No.: 18/768,870

(22) Filed: Jul. 10, 2024

(30) Foreign Application Priority Data
Jul. 10, 2023 (FR) 2307354

(51) Int. Cl. G11C 27/00; H10B 63/00; H10N 70/00; H10N 70/20

(52) U.S. Cl. CPC G11C 27/005; H10B 63/00; H10N 70/011; H10N 70/245; H10N 70/253; H10N 70/8836

(57) ABSTRACT

An electrochemical charge storage device includes an ionic transistor and an ionic capacitor, the ionic transistor including a reservoir layer forming an ion reservoir; a source electrode in contact with a part of the reservoir layer; a drain electrode in contact with another part of the reservoir layer, the drain electrode and the source electrode being physically separated from each other, the source electrode and the drain electrode each being made of an electrically conductive material; and a gate electrode of an electrically conductive material, the gate electrode being separated from the reservoir layer by an ionic conductive layer of an ionic conductive and dielectric material, the ionic conductive layer being in contact with the source electrode and with the drain electrode. The ionic capacitor includes two electrodes. The ionic capacitor includes an ionic conductive layer separating the two electrodes from the ionic capacitor.

### CROSS-REFERENCE TO RELATED APPLICATIONS

This application claims priority to French Patent Application No. 2307354, filed Jul. 10, 2023, the entire content of which is incorporated herein by reference in its entirety.

### FIELD

The technical field of the invention is that of charge storage components, in particular electrochemical charge storage components.

In particular, the invention relates to an electrochemical charge storage device that can be used in neuromorphic circuits.

### BACKGROUND

The use of artificial intelligence algorithms for a wide range of applications has exploded in recent years. These algorithms often require so-called neuromorphic architectures, which aim to mimic the synaptic processing that occurs in the human brain. Thus, neuromorphic architectures (or circuits) are electronic circuits designed to emulate the behaviour of biological neurons and neural networks.

Neuromorphic architectures, such as IBM™ Resistive Processing Units (RPUs), are partly based on resistive memory devices that use a network of crossed elements to achieve good performance in terms of memory density, energy efficiency and speed, by reducing data movement during computation and taking advantage of multi-level analogue states. Such resistive processing units can accelerate formation of deep neural networks using little energy. Indeed, it is possible to mimic the operation of a biological neuron using an array of resistive memories associated with respective synaptic weights.

Existing devices based on conductive filaments or phase-change materials suffer from excessive writing noise. In these devices, it is difficult to reduce noise and lower the switching voltage while ensuring long-term data retention, which represents a significant limitation in terms of accuracy, energy efficiency and scalability of these devices. To implement efficient neuromorphic systems, it is therefore preferable to use resistive memory elements that switch using a different mechanism to that used in filament-forming or phase-change devices.

For this reason, a new class of component has recently been studied for these neuromorphic applications: the ionic transistor, which can be used as a synaptic transistor. The operation of the ionic transistor is based on the displacement of ions between the source and drain, which enables the conductance value of the transistor to be modified. Such a transistor is especially described in the paper by Nguyen et al. An Ultralow Power LiₓTiO₂-Based Synaptic Transistor for Scalable Neuromorphic Computing”, published in Advanced Electronic Materials in 2022.

The ionic transistor can advantageously be in a plurality (several dozens) of non-volatile states, each state corresponding to a respective conductance value. In the scope of neuromorphic applications, the conductance values of the transistor correspond to the different synaptic weight values. However, there is a need to easily read these synaptic weight values for use in neuromorphic applications.

### SUMMARY

An aspect of the invention provides a solution to the previously discussed problem by providing an electrochemical charge storage device (hereinafter simply “electrochemical storage device”) comprising an ionic transistor and an ionic capacitor connected in series. Ionic transistors can be set in a multitude of conductance levels, and require a very small amount of energy to shift from one conductance level to another. Further, ionic capacitors also have high capacitance densities. This property makes it possible to connect them in series with ionic transistors. The series connection of an ionic transistor and an ionic capacitor effectively simulates synaptic connections and the simulation of the membrane potential of neurons, making it a viable approach for the design of complex and powerful neuromorphic systems.

In addition, it is possible to manufacture an ionic transistor and an ionic capacitor in series on a same substrate, by sharing a large part of the manufacturing steps for the two components. This makes it possible to obtain a compact device whose manufacture is relatively simple and inexpensive.

One aspect of the invention thus relates to an electrochemical charge storage device comprising an ionic transistor and an ionic capacitor,
the ionic transistor comprising:
a layer forming an ion reservoir, called reservoir layer;
a source electrode in contact with a part of the reservoir layer;
a drain electrode in contact with another part of the reservoir layer, the drain electrode and the source electrode being physically separated from each other, the source electrode and the drain electrode each being of an electrically conductive material; and
a gate electrode of an electrically conductive material, the gate electrode being separated from the reservoir layer by an ionic conductive layer of an ionic conductive and dielectric material, the ionic conductive layer being in contact with the source electrode and with the drain electrode;
the ionic capacitor comprising two electrodes, each of the two electrodes being of an electrically conductive material, the ionic capacitor comprising an ionic conductive layer separating the two electrodes of the ionic capacitor, the ionic conductive layer of the ionic capacitor being of an ionic conductive and dielectric material;
wherein the ionic transistor and the ionic capacitor are electrically connected in series.

The reservoir layer is a layer of a material comprising ions of some type (for example Li₊). The reservoir layer may be in a material referred to as an “ion insertion material”, or “insertion compound” or “ion intercalation material”, i.e. a material which allows the penetration of some type of ions, without altering its properties. In the following, the reservoir layer is also referred to as the “channel layer” or “ion intercalation material layer”. It is noted that, above, “ionic conductive material” designates a material which is conductive for the same ions as those of the reservoir layer.

When the ionic capacitor has a “stacked” structure on the substrate (in that the electrodes extend along a direction that corresponds to the main direction of the substrate), the terminology “top electrode/bottom electrode” can be used for the electrodes of the ionic capacitor. The bottom electrode corresponds to the electrode closest to the substrate, while the top electrode corresponds to the electrode furthest from the substrate.

By “electrically connected in series”, it is understood that one of the electrodes of the capacitor is connected to one of the electrodes (hereinafter referred to as the “bottom electrode” for the sake of simplification) among the source electrode and the drain electrode of the transistor. Thus, the source electrode of the transistor, the channel of the transistor, the drain electrode of the transistor and the bottom electrode of the capacitor are connected to each other. In other words, the output current of the transistor corresponds to the input current in the capacitor.

By connecting an ionic transistor and an ionic capacitor in series, it is possible to read the value of the conductance of the ionic transistor (and therefore of the synaptic weights, in a neuromorphic system) from the charging time of the ionic capacitor. It should be noted that the use of an ionic capacitor is important. For example, it is not contemplatable to replace it with a dielectric capacitor due to the wide range of possible conductance values of the ionic transistor, as this would lead to degradation of the dielectric capacitor. In addition, making a circuit connecting an ionic transistor and an ionic capacitor can be beneficially simplified because these components use common layers of materials. Thus, some manufacturing steps can be shared.

It is noted that the ionic transistor (or synaptic transistor) and the ionic capacitor (or ionic capacitor, or ionic supercapacitor) are two components known of the state of the art. However, in the state of the art, the ionic capacitor is used as an electrochemical storage element in its own right and is not connected in series with an ionic transistor in order to be able to read the conductance values thereof.

In embodiments of the invention, the ionic conductive layer of the ionic transistor and the ionic conductive layer of the ionic capacitor are of a same ionic conductive and dielectric material.

This property beneficially allows the ionic conductive layer of the ionic transistor and the ionic conductive layer of the ionic capacitor to be mutually deposited. In particular, these two ionic conductive layers can be formed from a same layer deposited and structured on the surface of a substrate onto which the source electrode, the channel and the drain electrode of the transistor as well as the bottom electrode of the ionic capacitor are mounted.

For example, the ionic conductive and dielectric material may be a lithium phosphorus oxynitride LiPON, a lithium silicon phosphorus oxynitride LiSiPON, a lithium germanium phosphorus sulphide LGPS, a lithium lanthanum zirconium oxide LiLaZrxO_{y} or a lithium lanthanum tantalum oxide LiLaTaOₓ.

LiPON can be used for an ionic transistor and an ionic capacitor operating on the basis of lithium Li₊ ions (i.e. whose operation relies on the circulation of Li₊ ions). In these embodiments, the channel of the ionic transistor can be made of a Li₊ ion insertion material, for example a transition metal oxide capable of intercalating Li₊ ions. It will be appreciated that the invention is applicable to other charge-carrying ions, for example Na₊, H₊, K₊, Cu₊ ions etc.

The electrically conductive material of which the electrodes of the ionic capacitor and/or the source, drain or gate electrodes of the ionic transistor are made may be, for example, one of: titanium (Ti), tungsten (W), molybdenum (Mo), nickel (Ni) or platinum (Pt).

The reservoir layer may be made, for example, from one of the following materials: titanium dioxide (TiO₂), lithium cobalt dioxide (LiCoO₂), lithium niobate (LiNbOₓ), tungsten trioxide (WO₃), vanadium oxide (VOₓ), nickel oxide (NiOₓ), manganese oxide (MnOₓ)—and generally transition metal oxides, molybdenum disulphide (MoS₂), graphene.

In some embodiments, the reservoir layer and the ionic conductive layer of the ionic transistor are made of a same ionic conductive and dielectric material.

In some embodiments, the ionic conductive layer of the ionic transistor and the ionic conductive layer of the ionic capacitor may have a same thickness.

Thus, these two ionic conductive layers can be formed by depositing a single layer of constant thickness and structuring it into two distinct parts, one corresponding to the ionic conductive layer of the ionic transistor and the other part corresponding to the ionic conductive layer of the ionic capacitor.

Beneficially, the ionic transistor and the ionic capacitor can be monolithically located on a same substrate.

By “located on a same substrate”, it is understood that the ionic transistor and the ionic capacitor are integrated on a same substrate wafer. This enables the two components to be co-integrated in parallel, with shared manufacturing steps. In particular, at least some layers come from a same deposited and structured layer of material. It should be noted that by substrate, it is meant the raw substrate (i.e. a Si wafer, for example) but also a raw substrate onto which one or more semiconductor or insulating layers have been deposited. By “monolithically”, it is meant “in a single block”. In other words, the ionic transistor and the ionic capacitor are integrated on the same substrate and form an assembly.

For example, the ionic transistor and the ionic capacitor may be mounted on a same level of the substrate.

In particular, the substrate may comprise, on a first level, CMOS-type components, and, on a second level, the ionic transistor and the ionic capacitor. For example, the ionic transistor and the ionic capacitor can be made in “Back End Of Line” on a substrate integrating CMOS, provided that maximum temperatures in the order of 450° C. are complied with.

In embodiments, the substrate may comprise a recess, wherein at least part of the ionic capacitor is housed in the recess. The recess may be a blind hole.

This increases the exchange area between the bottom and top electrodes of the ionic capacitor, and hence the capacitance value.

In these embodiments, one of the electrodes of the ionic capacitor, referred to as the bottom electrode, extends along an inner surface of the recess, the ionic conductive layer of the ionic capacitor at least partially covers the bottom electrode of the ionic capacitor, and the other electrode of the ionic capacitor, referred to as the top electrode, at least partially covers the ionic conductive layer of the ionic capacitor.

In embodiments, the source electrode of the ionic transistor, the drain electrode of the ionic transistor and one of the electrodes, referred to as the bottom electrode, of the ionic capacitor may be of a same electrically conductive material and have a same thickness.

This property makes it possible to simplify manufacture of these electrodes by depositing and structuring a single layer of electrically conductive material.

In particular, the bottom electrode of the ionic capacitor and one of the electrodes from among the drain electrode and source electrode of the ionic transistor may be common.

By “common”, it is understood that the device comprises a “continuous” layer (i.e. without discontinuities, for which there is no interruption) which acts both as the drain/source electrode of the ionic transistor and as the bottom electrode of the ionic capacitor. For example, one end of the continuous layer corresponds to the drain or source electrode of the transistor, and the other end to the bottom electrode of the capacitor.

In addition, the gate electrode of the ionic transistor and the other electrode, referred to as the top electrode, of the ionic capacitor may be of a same electrically conductive material. For example, this electrically conductive material may be (but need not be) the same material as that of the source electrode of the ionic transistor, the drain electrode of the ionic transistor and the bottom electrode of the ionic capacitor.

In particular, the gate electrode of the ionic transistor and the top electrode of the ionic capacitor may have a same thickness. Thus, these two electrodes can be formed from depositing and structuring a single layer of this electrically conductive material.

In some embodiments, the device may comprise a plurality of ionic transistors connected in parallel, each ionic transistor of the plurality of ionic transistors being connected in series with the ionic capacitor.

By “connected in parallel”, it is understood that the transistors have a common source electrode and a common drain electrode.

Another aspect of the invention relates to a circuit comprising an electrochemical storage device as defined above, the circuit further comprising a comparator block connected in series with an output of the ionic capacitor, the comparator block being configured to trigger a signal when a terminal voltage of the ionic capacitor reaches a reference voltage value.

In embodiments, the comparator block comprises an operational amplifier receiving, on one input, the terminal voltage of the ionic capacitor and, on another input, the reference voltage value, the signal being triggered when the terminal voltage of the ionic capacitor reaches the reference voltage value, the signal corresponding to a response of an artificial synapse.

In addition, the circuit may comprise a device configured to determine a time taken by the ionic capacitor for its terminal voltage to reach the reference voltage.

It is thus possible to determine the charging time of the ionic capacitor as a function of the time elapsed between generating a current flowing between the ionic transistor and the ionic capacitor and triggering the event, and to deduce therefrom an (approximate) value of the conductance of the ionic transistor, this charging time corresponding to a synaptic weight.

Another aspect of the invention relates to a method for manufacturing an electrochemical charge storage device as defined previously, this method successively comprises:
depositing, onto a substrate, a first layer of electrically conductive material, and structuring said first layer so as to obtain a first part of the first layer and a second part of the first layer having no point of contact, the first part of the first layer corresponding to one of a source electrode and a gate electrode of the ionic transistor, the second part of the first layer corresponding to the other of the source electrode and the drain electrode of the ionic transistor and to a first electrode of the two electrodes of the ionic capacitor;
depositing the reservoir layer, the reservoir layer being in contact with the source electrode and the drain electrode of the ionic transistor;
depositing an ionic conductive layer of an ionic conductive and dielectric material, and structuring the ionic conductive layer so as to obtain a first part of the ionic conductive layer and a second part of the ionic conductive layer having no point of contact, the first part covering the reservoir layer and being in contact with the source electrode and the drain electrode of the ionic transistor, the second part at least partially covering the first electrode of the ionic capacitor; and
depositing a second layer of electrically conductive material, and structuring said second layer so as to obtain a first part of the second layer and a second part of the second layer having no point of contact, the first part of the second layer partially covering the first part of the ionic conductive layer and having no point of contact with the first part of the first layer and the second part of the first layer, the second part of the second layer at least partially covering the second part of the ionic conductive layer and having no point of contact with the second part of the first layer, the first part of the second layer corresponding to the gate electrode of the ionic transistor, the second part of the second layer corresponding to a second electrode of the two electrodes of the ionic capacitor, the second electrode being distinct from the first electrode.

It is thus possible to manufacture an electrochemical storage device monolithically on a single substrate, by sharing some steps to manufacture both the elements making up the ionic transistor and the elements making up the ionic capacitor. This is made possible by the fact that the ionic transistor and the ionic capacitor are made up of layers of similar materials. This results in simplicity of manufacture, and a compact electrochemical storage device adapted to neuromorphic applications.

In particular, the deposition of at least one of the first layer of electrically conductive material, the ionic conductive layer and the second layer of electrically conductive material may be a conformal deposition.

By “conformal deposition”, it is meant a deposition embracing the surface on which the layer of material is formed and having a same thickness over its entire deposition surface.

Thus, a single layer can be deposited and then structured to form several elements of the electrochemical storage device according to the invention.

Finally, an aspect of the invention also relates to a charge storage method using an electrochemical storage device as defined above, comprising:
applying a voltage at the gate electrode of the ionic transistor, so as to set a predefined conductance value for the ionic transistor; and
generating a current flowing between the ionic transistor and the ionic capacitor, an intensity value of the output current of the ionic transistor corresponding to an input value of the input current of the ionic capacitor.

The invention and its different applications will be better understood upon reading the following description and upon examining the accompanying figures.

### BRIEF DESCRIPTION OF THE FIGURES

Further characteristics and benefits of the invention will become apparent upon reading the description, which may be read in conjunction with the figures. These figures are set forth by way of indicating and in no way limiting purposes of the invention.

FIGS. 1a and 1b represent an ionic transistor of the state of the art.

FIG. 2 represents an ionic capacitor of the state of the art.

FIG. 3 represents an example of a neuromorphic system comprising an electrochemical storage element according to one embodiment of the invention.

FIGS. 4a to 4f illustrate steps of a method for manufacturing an electrochemical storage element according to one embodiment of the invention.

FIG. 5 represents an example of a flow diagram of a method for manufacturing an electrochemical storage element according to one embodiment of the invention.

FIG. 6 represents an example of a flow diagram of a charge storage method using an electrochemical storage element according to one embodiment of the invention.

### DETAILED DESCRIPTION

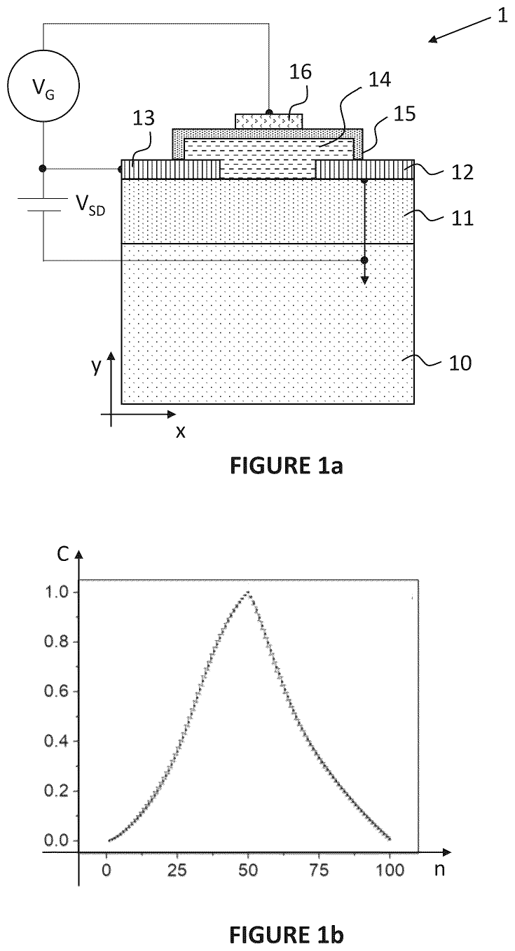

FIG. 1a represents an ionic transistor 1 according to the state of the art. The ionic transistor 1 is an analogue transistor mounted to a substrate 10, especially of silicon Si, covered with a layer 11 of dielectric material (for example, silicon dioxide SiO₂), which comprises a channel 14 having variable electrical conductivity, a source electrode 13 (also referred to simply as “source”) and a drain electrode 12 (also referred to simply as “drain”). It is noted that in some embodiments the assembly formed by the substrate 10 and dielectric layer 11 may be replaced with a single layer of dielectric material. The drain 12 and source 13 are separated from each other by the channel 14, so that the drain 12 and source 13 have no point of physical contact. For example, drain 12 and source 13 may be deposited onto two portions of a surface of layer 11 of dielectric material, both portions of the surface of layer 11 of dielectric material being spaced apart by, for example, a few tens of nanometres. The drain 12 and the source 13 are of an electrically conductive material. Channel 14 is of an ion-insertion material. It is noted that the source and drain electrodes may be interchanged (in particular, in FIG. 1a, electrode 12 may represent the source and electrode 13 may represent the drain).

The ionic transistor 1 further comprises a layer 15 of a material that is both ionic conductive and dielectric, separating the channel 14 from an electrode 16 called the gate, positioned at the upper surface of the layer 15 of material that is both ionic conductive and dielectric. The gate electrode 16 (also known simply as the “gate”) is of an electrically conductive material. Layer 15 therefore allows ion transport between channel 14 and gate electrode 16, but blocks electron transport. It is understood that layer 15 is conductive for the same ions as the ion-insertion material making up channel 14. For example, if channel 14 is of a material allowing intercalation of Li₊ ions, the material of layer 15 is conductive for Li₊ ions.

The ionic transistor 1 can be manufactured by successively depositing (and structuring) layers making it up (depositing the layers forming the drain 12 and the source 13, then depositing the layer 14 forming the channel, then depositing the layer 15 of ionic conductive and dielectric material, and finally depositing the layer 16 forming the gate electrode 16), for example by a lithography method (photolithography or electron lithography).

The channel 14 is of an ion insertion material, the electrical conductivity of which depends on its oxidation level. For example, the channel may be of an inert material such as lithiated components like LiₓCoO₂, LiₓNiO₂, LiₓMn₂O₄, LiₓV₂O₅, LiₓWO₃, LiₓMO₃, LiₓTi₅O₁₂, where x is the fraction of lithium in the component.

In a non-limiting manner, the channel 14 may comprise LiCoO₂, the layer 15 of ionic conductive and dielectric material may comprise lithium phosphorus oxynitride (LiPON), which is a material that can conduct Li₊ ions from the channel 14.

It is noted that other layers may be added to the ionic transistor 1, for example an interlayer of an ion insertion material located between the channel layer 14 and the layer 15 of ionic conductive and dielectric material. Furthermore, it is noted that the structure of the ionic transistor may differ from the example represented in FIG. 1a. For example, according to some embodiments, channel layer 14 may completely cover drain 12 and source 13, as in U.S. application Ser. No. 10/429,343 for example.

The oxidation level of channel 14 can be varied by applying a voltage VG applied between gate 16 and source 13. When a voltage VG is applied between gate 16 and source 13, this induces migration of ions between gate 16 and channel 14, which has the effect of modifying electrical conductance of channel 14 between source 13 and drain 12, and hence the logic state of the transistor, a logic state being associated with a respective electrical conductance value of the transistor. The different (normalised) conductance values of the ionic transistor as a function of the voltage applied between gate 16 and source 13 are represented in FIG. 1b. By conductance of the ionic transistor, it is meant the electrical conductance of channel 14.

To obtain the curve of FIG. 1b, successive voltage square slots have been applied between gate 16 and source 13. In the example of FIG. 1b, each voltage square slot has an amplitude of ±100 mV and a width of 0.1 second. These values are given by way of non-limiting example. The curve of FIG. 1b represents the variation in transistor conductance (ordinate) as a function of the number n of voltage square slots (abscissa). To obtain the curve of FIG. 1b, 50 successive pulses of negative amplitude have been applied (increasing part of the curve, called the potentiation phase), then 50 successive pulses of positive amplitude have been applied (decreasing part of the curve, called the depression phase).

It appears from FIG. 1b that the conductance of channel 14 can be reversibly modified according to the voltage VG applied between gate 16 and source 13. Furthermore, the variation in the value of conductance is linear during the application of a non-zero constant value of voltage. It increases linearly when a voltage square slot of negative amplitude is applied, and decreases linearly when a voltage square slot of positive amplitude is applied. Furthermore, the application of a voltage square slot of positive amplitude “cancels out” effects of the application of a voltage square slot of the same duration and opposite amplitude (and vice versa), in that it returns the conductance value to the initial value.

It is thus possible to modify conductance of the ionic transistor 1 of FIG. 1a by varying the value of the voltage VG applied between the gate 16 and the source 13. Once the ionic transistor has a certain conductance value, a voltage V_{SD} is applied between source 13 and drain 12 and a current circulates, the value of the current intensity being set by the conductance value of the transistor.

The different conductance values associated with the different current pulse numbers correspond to logic states (or “conductance states”). Each logic state is non-volatile, and the transition from one logic state to the next requires very little energy (for example, a quantity of energy per active area in the order of fJ/μm²). Further, as appears from FIG. 1b, a large number (several tens) of logic states can be achieved in potentiation and depression in a controlled manner (via the applied voltage V_{G}), with, as mentioned above, a response linearity that is a function of the conductance range considered.

It is noted that the transition speed between two successive logic states of the ionic transistor partly depends on the thickness of the channel layer 14 (the thickness corresponding to the dimension along the axis y in FIG. 1a): the thinner the channel layer 14, the higher the transition speed between two successive logic states. The thickness of the channel layer 14 can thus be set, for example, between 1 and 500 nm.

The transition speed between two successive logic states also partly depends on the thickness of the layer 15 of ionic and dielectric conductive material: the thinner the layer 15 of ionic and dielectric conductive material, the higher the transition speed between two successive logic states. The thickness of the layer 15 of ionic conductive and dielectric material can thus be set, for example, between 1 and 200 nm.

As detailed above, the ionic transistor is an analogue transistor allowing several tens of states (which is difficult to obtain today from dielectric transistors and with resistive memories), which makes it a component of choice for reproducing the operation of synapses, which, in the human brain, enable neurons to be connected together. In the human brain, neurons are activated when the synapses have accumulated a number of electrical impulses, which is made possible by a transistor with several dozen states.

Furthermore, the ionic transistor makes use of the same electrochemical reaction as a synapse, which gives it excellent energy efficiency, of the same order of magnitude as a human brain synapse.

These properties make the ionic transistor particularly adaptable for neuromorphic applications.

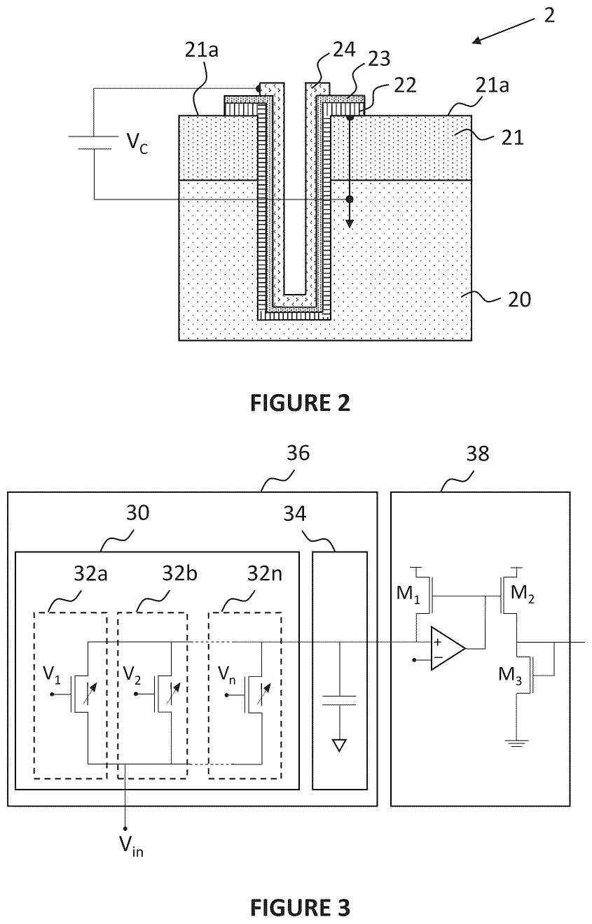

FIG. 2 represents an ionic capacitor 2 (also known as a supercapacitor) according to the state of the art.

An ionic capacitor is an electrochemical storage component, of the supercapacitor type, comprised of materials exclusively in solid form. An ionic capacitor can be charged and discharged by connecting it to an electrical circuit. Charges are stored by virtue of changes in the materials making up the ionic capacitor during charging and discharging. When a voltage is applied across the ionic capacitor, depletions/concentrations of ions occur at the two ionic conductor/electrode interfaces.

As represented in FIG. 2, an ionic capacitor 2 typically comprises a substrate 20 covered with a first dielectric layer 21. The substrate 20 is a raw (i.e. unprocessed) substrate, or it may have already undergone processing such that other electronic components or layers are already present thereon. In the example of FIG. 2, the substrate 20 and dielectric layer 21 of FIG. 2 have a cavity covered by a layer 22 of electrically conductive material passing therethrough. The cavity is here a blind hole, the bottom of which is located at the substrate 20, in proximity to the lower surface of the substrate 20. This layer 22 of electrically conductive material at least partially covers the “free” surface 21a of the first dielectric layer 21 (i.e. the surface 21a which is not against the substrate 20 and which is not along the cavity formed) on either side of the cavity. The layer 22 of electrically conductive material forms one of the electrodes of the ionic capacitor 2, referred to here as the “bottom electrode”. The layer 22 of electrically conductive material is (at least partially) covered with a layer 23 of a material that is both an ionic conductor and a dielectric (ionic dielectric). This layer 23 of ionic conductor is (at least partially) covered with a layer 24 of electrically conductive material, which forms the other electrode of the ionic capacitor 2, called the “top electrode”. The bottom electrode 22 and the top electrode 24 are thus electrically insulated from each other by the layer 23, which nevertheless allows ions to circulate between both electrodes 22 and 24. A charging voltage V_{C} therefore appears between the input and output of the ionic capacitor 2.

It is noted that the example represented in FIG. 2 is not limiting and that other configurations are possible. For example, in some configurations, the cavity only passes through the first dielectric layer 21. Further, the shape of the cavity is not limiting, and may be replaced with a pore in a porous dielectric layer 21, as described in EP3570307.

In the example of FIG. 2, the bottom electrode 22, the ionic dielectric layer 23 and the top electrode 24 of the ionic capacitor 2 are disposed according to a MIM (metal-insulator-metal) structure wherein the insulator is an ion-conducting dielectric (ionic dielectric), but other configurations are possible, for example a MOIM (metal-oxide-ionic dielectric-metal) configuration wherein an oxide layer is interposed between the bottom electrode and the ionic dielectric layer, as in application EP3570307.

The presence of the cavity in the assembly formed by the substrate 20 and the dielectric layer 21 of FIG. 2 is not mandatory, but it beneficially makes it possible to increase the effective surface area for accumulating charges between both electrodes 22 and 24. Furthermore, it is noted that the ionic capacitor 2 can be formed in a planar or three-dimensional configuration, a three-dimensional configuration beneficially making it possible to increase the effective surface area for accumulating charges between both electrodes per unit of geometric surface area on the substrate, and therefore to increase the capacitance density of the ionic capacitor 2 (by varying the geometry of the ionic capacitor alone).

The application of a voltage V_{C} between the bottom electrode 22 and the top electrode 24 induces two distinct physical phenomena: on the one hand, establishment of an electrochemical double layer between the ionic conductor 23 and both electrodes 22 and 24 (appearance of an ionic capacitor), and on the other hand, dielectric bias of the ionic conductor 23 (appearance of a dielectric capacitance). The combination of these two phenomena gives the ionic capacitor a very high power density per unit area, in the order of a few tens of μF/mm², i.e. several orders of magnitude higher than the power densities of MOS or MIM type dielectric components.

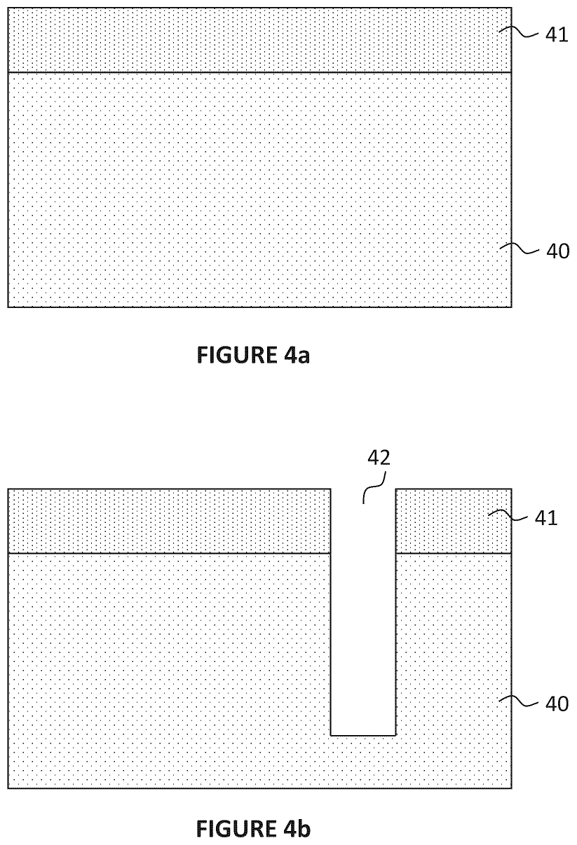

FIG. 3 represents one example of a neuromorphic system comprising an electrochemical storage element according to one embodiment of the invention.

The electrochemical storage element 36 of FIG. 3 comprises a resistive element 30 and a capacitive element 34 connected in series. The resistive element 30 comprises a single ionic transistor or several ionic transistors 32a, 32b, . . . , 32n connected in parallel (in that each transistor has a common source and drain), as represented in FIG. 3. Each ionic transistor 32a, 32b, . . . , 32n models a synapse and is associated with a respective conductance value which corresponds to a respective synaptic weight, which can be stored in the capacitor 34 (together with the other synaptic weights of the other transistors). A voltage V₁, V₂, . . . , Vₙ is applied between the gate and the source of each of the ionic transistors 32a, 32b, . . . , 32n so as to vary their conductance values. When a voltage Vᵢₙ is applied between the source and the drain, this generates a current whose intensity is a function of the total conductance of the resistive element 30.

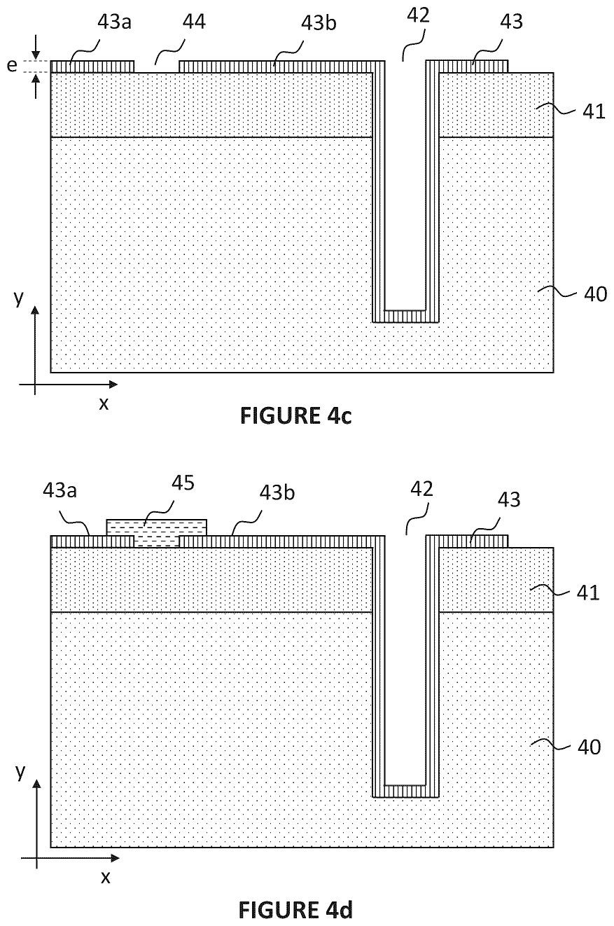

The connection, in series, of a resistive element 30 from ionic transistors 32a, 32b, . . . , 32n and of a capacitive element 34 from at least one ionic capacitor has the following benefits. On the one hand, the resistive element can be in a plurality of non-volatile analogue states (which correspond to different conductance values), the transition from one state to another requiring a small amount of energy, which makes the resistive element 30 a component particularly suitable for neuromorphic applications. However, because of the wide range of conductance values of the resistive element 30, it is desirable to have a capacitor that can accept large values of charge quantities (in coulomb) at its terminals without saturating or deteriorating. In this respect, the ionic capacitive element 34, which has a high capacitance density, is a storage component particularly suitable for receiving the output current from the resistive element 30. Furthermore, as detailed below with reference to FIGS. 4a to 4f, the resistive element 30 and the capacitive element 34 can be made from the same materials, which enables them to be manufactured on a same substrate with shared steps, from same layers of materials, potentially without the same need to adjust the thicknesses.

When an input voltage Vᵢₙ is applied between the source and drain of the ionic transistor(s) 32a, 32b, . . . , 32n of the resistive element 30, the resistive element 30 enters a certain analogue state corresponding to a certain conductance value, which induces a current as an input to the capacitive element 34. The capacitive element 34 then is charging, and the terminal voltage of the capacitive element 34 depends on the input current (hence the current delivered by the resistive element 30).

As mentioned above, the capacitive element 34 has to be able to withstand a wide range of charging cycles without saturating or degrading, due to the wide range of conductance values of the resistive element 30. For example, a dielectric capacitive element would not be able to perform such a function (or else it would be necessary to use a large number of dielectric capacitors, which is undesirable for reasons of cost and overall size). For this reason, an ionic capacitive element is particularly suitable.

In the example of FIG. 3, a comparator circuit 38 is connected in series with the output of the electrochemical storage element 36. For example, the comparator circuit 38 comprises an operational amplifier configured to trigger an operation when the terminal voltage of the capacitive element 34 reaches a predetermined threshold. In the example of FIG. 3, the comparator circuit 38 is a CMOS-type analogue sensor involving three transistors M₁, M₂, M₃, but not limiting thereto, any comparator circuit may be used.

A circuit such as that represented in FIG. 3 can be used for neuromorphic applications. Each ionic transistor 32a, 32b, . . . , 32n corresponds to a respective synapse. The ionic transistors 32a, 32b, . . . , 32n are indeed particularly suitable for playing the role of artificial synapses, since they have variable conductances as a function of the voltage applied thereto as an input, and their states are non-volatile, which makes it possible to reproduce the synaptic characteristic known as “spike timing dependent plasticity” (STDP), according to which the more the synapse is stimulated, the more learning improves. The capacitive element 34 simulates the action potential of a biological neuron, which ensures separation of electrical charges across the cell membrane. The assembly of FIG. 3 thus makes it possible to reproduce the operation of a neuron, by triggering an action (via the comparator circuit 38) when a certain threshold of activation of the artificial neuron is reached (here, when the capacitance of the capacitive element 34 reaches a certain value), in a similar way to the action potential of the neuron in the human brain.

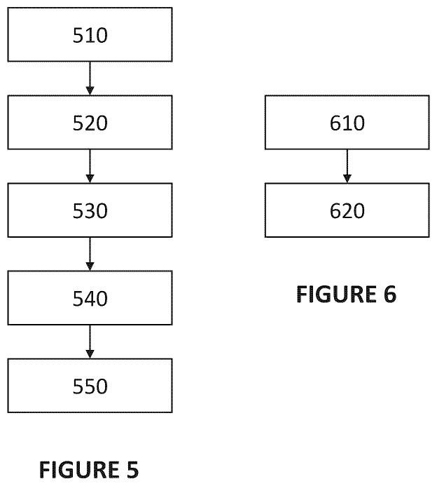

In other words, the operation of the electrochemical storage element 36 may therefore comprise the following steps, represented in FIG. 6:
write step: an electrical signal (voltage V₁, . . . , Vₙ or current) is applied (step 610) between the source and gate of each ionic transistor 32a, . . . , 32n so that the latter enters a given conductance state;
read step: an electrical signal (voltage Vᵢₙ or current) is applied (step 620) between the source and drain of each ionic transistor 32a, . . . , 32n, which generates a current, called the “read current”, which is transmitted to the capacitive element 34, allowing charge storage proportional to the read current.

It is noted that the electrochemical storage element 36 can be viewed as a series-connected RC circuit. The associated time constant is therefore approximately equal to R×C, where R designates the resistance value of the resistive element 30 (and therefore, for a single transistor 32a, the inverse of the conductance value of the transistor) and C the value of the capacitance of the capacitive element 34. It is thus possible to determine the resistance (or conductance) value of the resistive element 30, and hence the synaptic weight, from the charging time of the capacitive element 34. The charging time may be determined, for example, by measuring the time between generation of an input current to the capacitive element 34 and triggering of the event by the comparator circuit 36.

As mentioned previously, the electrochemical storage element 36 has the benefit that it can be made on a single substrate, by deposition of successive layers, as now described with reference to FIGS. 4a to 4f.

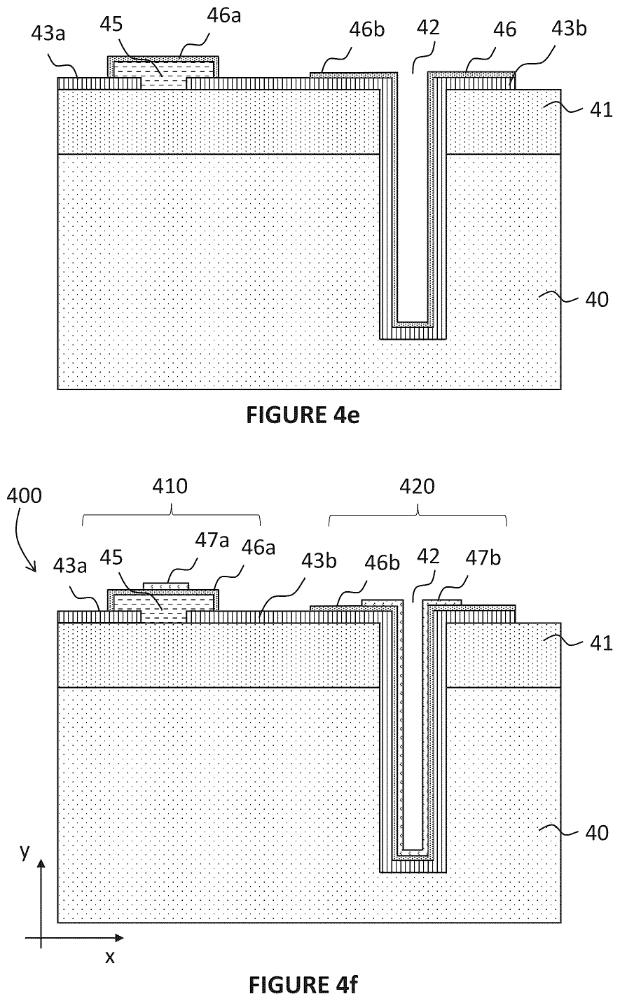

FIGS. 4a to 4f illustrate steps of a method for manufacturing an electrochemical storage element according to one embodiment of the invention. The flow chart for this manufacturing method is represented in FIG. 5.

In a first step 510 (FIG. 5) of the method, an electrically insulating layer can be deposited onto a substrate. This step is illustrated in FIG. 4a.

As represented in FIG. 4a, an electrically insulating layer 41 (for example of a dielectric material) is formed on a substrate 40, for example by a full wafer deposition method. The substrate 40 may be a wafer of semiconductor material. In some embodiments, this wafer integrates one or more components such as conventional transistors or microsystems. In particular, the storage device of the present invention can be performed in the “Back End Of Line”, i.e. after the CMOS level and higher levels have been made, in the same way as the contacts. It is noted that the ionic conductive layer 41 may constitute the substrate on its own (in some embodiments, therefore, there may be only one dielectric layer 41 which replaces the two layers 40 and 41 of FIGS. 4a to 4f).

The dielectric layer 41 may be comprised of one or more materials for electrical insulation, for example an oxide, nitride, oxynitride, or any material or combination of materials that can act as a chemical and electrical passivation between the substrate 40 and the memory element.

In a non-limiting embodiment, the substrate 40 may be a silicon wafer and the layer 41 may be a silicon oxide layer.

Further, in the first step 510 of the method represented in FIG. 5, the assembly comprised of the substrate and ionic conductive layer may be structured to form a recess for receiving the ionic capacitor. This structuring is represented in FIG. 4b.

As represented in FIG. 4b, the “substrate 40/dielectric layer 41” assembly can be structured to create an opening 42 (or “cavity” or “groove”) perpendicularly to the surface plane of the dielectric layer 41 and the substrate 40. This structuring is carried out through the dielectric layer 41 and the substrate 40, and stops in the substrate volume without passing through it. In the example of FIG. 4b, the opening 42 is a blind hole in the dielectric layer 41 which passes through part of the substrate 40, and the bottom of which is located in proximity to the lower surface of the substrate 40. It is noted that, according to the embodiments, the opening 42 may pass through the substrate to a variable depth, or even only through all or part of the dielectric layer 41 (and therefore not pass through the substrate 40). In some embodiments, structuring may be performed by a photolithography technique (typically comprising deposition of a layer of resin by spin coating on the “substrate 40/dielectric layer 41” assembly, exposure through a mask and development of the resin exposed) followed by plasma etching.

As mentioned with reference to FIG. 2, the presence of the opening 42 is not mandatory, but it beneficially makes it possible to increase the effective charge surface area for accumulation between both electrodes 43b and 47b.

Referring again to FIG. 5, in a step 520, a first layer of an electrically conductive material can be deposited onto the surface of the substrate, and structured in two parts having no points of contact, one acting as the source electrode of the ionic transistor, and the other comprising both the drain electrode and the bottom electrode of the ionic capacitor.

This step 520 is represented in FIG. 4c: a layer 43 of electrically conductive material is formed on part of the surface of the dielectric layer 41 and at the opening 42 if necessary. The layer 43 of electrically conductive material comprises two parts 43a, 43b separated by a gap 44, such that both portions 43a, 43b of the layer of electrically conductive material 43 have no point of contact with each other and are not electrically connected. In the example of FIG. 4c, part 43b of the layer 43 of electrically conductive material covers part of the unstructured surface of the “substrate 40/dielectric layer 41” assembly (i.e. the part of the surface of the “substrate 40/dielectric layer 41” assembly that is not level with the opening 42) as well as the walls and bottom of the opening 42. As described hereinafter, part 43a acts as the “source” of the ionic transistor of the storage component, and the part 43b acts both as the “drain” of the ionic transistor of the storage component and as the bottom electrode of the ionic capacitor of the storage component. It is noted that the source and drain electrodes may be interchanged (in particular, electrode 43a may represent the drain and electrode 43b may represent the source).

The layer 43 of electrically conductive material may typically be produced by deposition onto the entire surface of the structured “substrate 40/dielectric layer 41” assembly of FIG. 4b (including the walls and bottom of the opening 42), then by structuring in order to make the gap 44 and to give the desired shape and dimensions to the different parts of the layer 43. For example, layer 43 may be deposited by vacuum sputtering, and structuring may be achieved by photolithography followed by dry etching.

In some embodiments, the deposition of the layer 43 of electrically conductive material can beneficially be a conformal deposition on the surface of the structured “substrate 40/dielectric layer 41” assembly, i.e. its thickness is constant over the entire surface. This simplifies the method for manufacturing the electrochemical storage element, since a single layer can be deposited along the surface without the need to vary the thickness by adding additional layers.

In some embodiments, the layer 43 may be a titanium metal layer having a thickness e (which corresponds to the dimension along the axis y in FIG. 4c, i.e. along the direction orthogonal to the surface of substrate 40) of between 10 and 200 nm, for example equal to 100 nm.

Referring again to FIG. 5, in a step 530, a layer of an ion insertion material called a channel layer is deposited at the gap between the source electrode and the drain electrode of the ionic transistor, so as to be in contact with both the source electrode and the drain electrode of the ionic transistor.

This step 530 is illustrated in FIG. 4d: a layer 45 of an ion insertion material is formed and structured so as to cover the part of the layer 41 located at the gap 34, as well as portions of the parts 43a and 43b of the layer 43, said portions including the ends of the parts 43a and 43b located at the gap 44. As described hereinafter, this layer 45 constitutes the channel of the ionic transistor of the storage component, and is therefore in contact with the source 43a, the drain 43b and the part of the layer 41 located at the gap 44.

The channel 45 is comprised of an ion insertion material making it possible to intercalate and de-intercalate ions under the application of an electric field and, thus, to change the electrical conductivity of the channel 45 as a function of the intercalation rate. For example, the material making up channel 45 may be a transition metal oxide, and more particularly a metal based on titanium dioxide (TiO₂) nanoparticles having a size of about 10 nm, capable of intercalating lithium (Li₊) ions. Channel 45 may, for example, have a thickness in the order of a few nanometres to a few tens of nanometres.

Referring again to FIG. 5, in a step 540, a layer of a material that is both ionic conductive and dielectric may be deposited onto the surface of the element obtained at the end of step 530, and then structured into two parts having no point of contact. The first part covers the channel layer and is in contact with the source electrode and the drain electrode. The second part partially covers the bottom electrode of the ionic capacitor.

This step 540 is illustrated in FIG. 4e: a layer 46 of ionic conductor and dielectric is deposited onto the surface and structured. The layer 46 is conductive for the same ions as the ion insertion material making up the channel 45. For example, if the channel 45 is of a material allowing intercalation of Li₊ ions, the material of the layer 46 is conductive for Li₊ ions.

The ionic and dielectric conductor layer 46 comprises two parts 46a, 46b which have no point of contact. One part 46a covers the channel 45 so as to be in contact with the source 43a and drain 43b of the ionic transistor of the electrochemical storage element. The other part 46b covers a portion of the part 43b of the layer 43 of electrically conductive material, said portion of the part 43b of the layer 43 of electrically conductive material including the portion of the part 43b of the layer 43 of electrically conductive material at the opening 42.

Layer 46 is comprised of an ionic conductive and dielectric material, which allows ions to circulate on the one hand between source 43a and drain 43b via the channel of the ionic transistor of the storage element, and on the other hand between both electrodes 43b and 47b of the ionic capacitor of the storage element, while providing electrical insulation therebetween. For example, this material may be a lithium phosphorus oxynitride (LiPON). Layer 46 may be a few tens to a few hundreds of nm thick, for example 100 nm. In some embodiments, this layer 46 is deposited by magnetron sputtering. Structuring may be performed by photolithography, for example.

In some embodiments, the deposition of the layer 46 of ionic conductive and dielectric material may beneficially be a conformal deposition onto the surface of the element of FIG. 4d.

Finally, during a step 550 of FIG. 5, a layer of an electrically conductive material may be deposited onto the surface of the element obtained at the end of step 540, and then structured into two parts having no point of contact. The first part partially covers the first part of the layer deposited in step 540 and is in contact with neither the source electrode nor the drain electrode. This first part forms the gate electrode of the ionic transistor. The second part at least partially covers the second part of the layer deposited in step 540, and is not in contact with the bottom electrode of the ionic capacitor. This second part forms the top electrode of the ionic capacitor.

This step 550 is illustrated in FIG. 4f, wherein a layer of an electrically conductive material is deposited onto at least part of the layer 46. This layer comprises two parts 47a, 47b which have no point of contact. The first part 47a covers a part of the surface of the part 46a of the layer 46 and forms the gate of the ionic transistor of the storage element. The second part 47b at least partially covers the part 46b of the layer 46 and forms the top electrode of the ionic capacitor of the storage element. In some embodiments, the deposition of the layer 47 of electrically conductive material may beneficially be a conformal deposition onto the surface of the element of FIG. 4e.

For example of the layer 47a, 47b may be a titanium metal layer having a thickness of 100 nm, deposited by vacuum sputtering. Structuring of the layer 47a, 47b can be achieved, for example, by photolithography and dry etching.

The above exemplary embodiments focus on a memory device operating on Li₊ lithium ions, but it is entirely possible to use other charge-carrying ions, such as Na₊, H₊, K₊, Cu₊, etc., in the memory device.

The electrochemical energy storage element 400 of FIG. 4f is represented in a cross-section view on the (x, y) plane. In one or more embodiments, the channel width may be less than 200 nm, such as less than 20 nm. The channel width corresponds to the dimension along the axis z (z being the third axis of an orthonormal reference frame (x, y, z)) of the channel 45 of the ionic transistor 420. The width of the ionic capacitor 420 (i.e. the dimension of the ionic capacitor 420 along the axis z) may be less than 2 um, such as than 1 um. The depth of ionic capacitor 420 (i.e. its dimension along the axis y) may be greater than 2 um, such as greater than 5 um.

The electrochemical storage element 400 obtained at the end of the different steps represented in FIGS. 4a to 4f comprises an ionic transistor 410 (with a similar structure to the ionic transistor 1 represented in FIG. 1a) and an ionic capacitor 410 (with a similar structure to the ionic capacitor 2 represented in FIG. 2) connected in series. Assuming that the ionic transistor 410 is in a given conductance state, when a voltage is applied between the source 43a and drain 43b of the ionic transistor 410, this generates a current which is transmitted to the ionic capacitor 420 via the layer 43b which acts both as the drain of the ionic transistor 410 and as the bottom electrode of the ionic capacitor 420, thus generating charge storage at the ionic capacitor 420.

The ionic transistor 410 and the ionic capacitor 420 are monolithically formed on the same level of the substrate 40. As is apparent from above, such an element can be manufactured by sharing some of the manufacturing steps of the transistor and the ionic capacitor (depositing a same layer for both components and structuring).

The element 400 of FIG. 4f is one example of an electrochemical storage element 36 as represented with reference to FIG. 3, wherein the resistive element 30 comprises a single ionic transistor 32a (the component 410) and wherein the capacitive element 34 comprises a single ionic capacitor 420. It will be appreciated that the storage element 400 of FIG. 4f can be modified to comprise several ionic transistors 410 in parallel. For example, in a 3D structure, a plurality of ionic transistors such as the ionic transistor 410 may be made in parallel and connected in series to an ionic capacitor 420.

It will be appreciated that the present invention is not limited to the embodiments described above by way of examples. It extends to other alternatives. For example, other components may be interposed between the ionic transistor and the ionic capacitor. The ionic transistor and/or the ionic capacitor may also comprise additional layers. For example, an interlayer in an ion insertion material dissociated from that of the ionic transistor can be implemented in the architecture of the ionic capacitor, so as to have a hybrid capacitor. For example, this interlayer can be inserted at the ionic capacitor, between layer 43b and layer 46b of FIG. 4f, i.e. between the bottom electrode and the ionic conductive layer of the ionic capacitor. Such an implementation makes it possible to further increase the value of the capacitance density (in practice, this can be doubled compared with an isoarchitecture without an interlayer), as described for example in the paper by V. Sallaz et al. “Hybrid All-Solid-State Thin-Film Micro-supercapacitor Based on a Pseudocapacitive Amorphous TiO₂ Electrode”, ACS Appl. Energy Mater. 2023, 6, 1, 201-210. Such an interlayer can be obtained from the manufacturing method of FIG. 5: in step 530, the layer of ion insertion material can be deposited onto the entire surface, and structured into two disjoint parts: one corresponding to the channel layer of the ionic transistor, the other corresponding to the interlayer of the ionic capacitor.

The articles “a” and “an” may be employed in connection with various elements and components of compositions, processes or structures described herein. This is merely for convenience and to give a general sense of the compositions, processes or structures. Such a description includes “one or at least one” of the elements or components. Moreover, as used herein, the singular articles also include a description of a plurality of elements or components, unless it is apparent from a specific context that the plural is excluded.

It will be appreciated that the various embodiments and aspects of the inventions described previously are combinable according to any technically permissible combinations. For example, various aspects of the present disclosure may be used alone, in combination, or in a variety of arrangements not specifically described in the embodiments described in the foregoing and is therefore not limited in its application to the details and arrangement of components set forth in the foregoing description or illustrated in the drawings. For example, aspects described in one embodiment may be combined in any manner with aspects described in other embodiments.

The present invention has been described and illustrated in the present detailed description and in the figures of the appended drawings, in possible embodiments. The present invention is not however limited to the embodiments described. Other alternatives and embodiments may be deduced and implemented by those skilled in the art on reading the present description and the appended drawings.

In the claims, the term “includes” or “comprises” does not exclude other elements or other steps. The different characteristics described and/or claimed may be beneficially combined. Their presence in the description or in the different dependent claims do not exclude this possibility. The reference signs cannot be understood as limiting the scope of the invention.

1. An electrochemical charge storage device comprising an ionic transistor and an ionic capacitor,
the ionic transistor comprising
a reservoir layer forming an ion reservoir;
a source electrode in contact with a part of the reservoir layer;
a drain electrode in contact with another part of the reservoir layer, the drain electrode and the source electrode being physically separated from each other, the source electrode and the drain electrode each being made of an electrically conductive material; and
a gate electrode of an electrically conductive material, the gate electrode being separated from the reservoir layer by an ionic conductive layer of an ionic conductive and dielectric material, the ionic conductive layer being in contact with the source electrode and with the drain electrode;
the ionic capacitor comprising two electrodes, each of the two electrodes being of an electrically conductive material, the ionic capacitor comprising an ionic conductive layer separating the two electrodes from the ionic capacitor, the ionic conductive layer of the ionic capacitor being of an ionic conductive and dielectric material,
wherein the ionic transistor and the ionic capacitor are electrically connected in series.

2. The device according to claim 1, wherein the ionic conductive layer of the ionic transistor and the ionic conductive layer of the ionic capacitor are of a same ionic conductive and dielectric material.

3. The device according to claim 2, wherein the ionic conductive and dielectric material is a lithium phosphorus oxynitride LiPON, a lithium silicon phosphorus oxynitride LiSiPON, a lithium germanium phosphorus sulphide LGPS, a lithium lanthanum zirconium oxide LiLaZrₓO_{y} or a lithium lanthanum tantalum oxide LiLaTaOₓ.

4. The device according to claim 1, wherein the reservoir layer and the ionic conductive layer of the ionic transistor are of a same ionic conductive and dielectric material.

5. The device according to claim 1, wherein the ionic conductive layer of the ionic transistor and the ionic conductive layer of the ionic capacitor have a same thickness.

6. The device according to claim 1, wherein the ionic transistor and the ionic capacitor are monolithically located on a same substrate.

7. The device according to claim 6, wherein the ionic transistor and the ionic capacitor are located on a same level of the substrate.

8. The device according to claim 6, wherein the substrate comprises a recess, wherein at least a part of the ionic capacitor is housed in the recess.

9. The device according to claim 1, wherein the source electrode of the ionic transistor, the drain electrode of the ionic transistor and one of the electrodes, forming a bottom electrode, of the ionic capacitor are of a same electrically conductive material and have a same thickness.

10. The device according to claim 9, wherein the bottom electrode of the ionic capacitor and one of the electrodes among the drain electrode and the source electrode of the ionic transistor are common.

11. A circuit comprising an electrochemical charge storage device according to claim 1, the circuit further comprising a comparator block connected in series with an output of the ionic capacitor, the comparator block being configured to trigger a signal when a terminal voltage of the ionic capacitor reaches a reference voltage value.

12. The circuit according to claim 11, wherein the comparator block comprises an operational amplifier receiving on one input the terminal voltage of the ionic capacitor and on another input the reference voltage value, the signal being triggered when the terminal voltage of the ionic capacitor reaches the reference voltage value, the signal corresponding to a response of an artificial synapse.

13. The circuit according to claim 11, further comprising a device for determining a time taken by the ionic capacitor for its terminal voltage to reach the reference voltage.

14. A method for manufacturing an electrochemical charge storage device according claim 1, the method successively comprising:
depositing, onto a substrate, a first layer of electrically conductive material, and structuring said first layer so as to obtain a first part of the first layer and a second part of the first layer having no point of contact, the first part of the first layer corresponding to one of a source electrode and a gate electrode of the ionic transistor, the second part of the first layer corresponding to the other of the source electrode and the drain electrode of the ionic transistor and to a first electrode of the two electrodes of the ionic capacitor;
depositing the reservoir layer, the reservoir layer being in contact with the source electrode and drain electrode of the ionic transistor;
depositing an ionic conductive layer of an ionic conductive and dielectric material, and structuring the ionic conductive layer so as to obtain a first part of the ionic conductive layer and a second part of the ionic conductive layer having no point of contact, the first part covering the reservoir layer and being in contact with the source electrode and the drain electrode of the ionic transistor, the second part at least partially covering the first electrode of the ionic capacitor;
depositing a second layer of electrically conductive material, and structuring said second layer so as to obtain a first part of the second layer and a second part of the second layer having no point of contact, the first part of the second layer partially covering the first part of the ionic conductive layer and having no point of contact with the first part of the first layer and the second part of the first layer, the second part of the second layer at least partially covering the second part of the ionic conductive layer and having no point of contact with the second part of the first layer, the first part of the second layer corresponding to the gate electrode of the ionic transistor, the second part of the second layer corresponding to a second electrode of the two electrodes of the ionic capacitor, the second electrode being distinct from the first electrode.

15. The method for manufacturing according to claim 14, wherein the deposition of at least one of the first layer of electrically conductive material, the ionic conductive layer and the second layer of electrically conductive material is a conformal deposition.

16. A charge storage method using an electrochemical storage device according to claim 1, comprising:
applying a voltage at the gate electrode of the ionic transistor, so as to set a predefined conductance value for the ionic transistor, and
generating a current flowing between the ionic transistor and the ionic capacitor, an intensity value of the output current of the ionic transistor corresponding to an input value of the input current of the ionic capacitor.
